(19) United States
(12) Patent Application Publication
(10) Pub. No.: US 2022/0186357 A1
(43) Pub. Date: Jun. 16, 2022

(54) APPARATUS AND METHOD FOR DEPOSITING THIN SPUTTERED FILM

(71) Applicant: Ark Power Tech. Corp., Coppell, TX (US)

(72) Inventors: Juhong Park, Denton, TX (US); Sungyong In, Germantown, MD (US)

(21) Appl. No.: 17/525,771

(22) Filed: Nov. 12, 2021

Related U.S. Application Data
(60) Provisional application No. 63/113,178, filed on Nov. 12, 2020.

(51) Int. Cl. C23C 14/34; C23C 14/56; C23C 14/50; C23C 14/54

(52) U.S. Cl. CPC C23C 14/34; C23C 14/542; C23C 14/50; C23C 14/56

(57) ABSTRACT

Mass production of nanoscale thin layer is essential for industrial uses. Reel-to-reel sputtering method is an effective deposition means for producing nanoscale thin layers on a flexible substrate in a vacuum chamber. The present disclosure provides an apparatus for depositing a thin sputtered film on the flexible substrate. By way of example, the apparatus includes a reel-to-reel sputtering system including a deposition or processing chamber, one or more sputtering devices in the processing chamber, a mask device disposed in the processing chamber, and one or more mask supporters coupled to the mask device. Further, the sputtering operation occurs in the processing chamber when the one or more sputtering devices are in operation as a flexible substrate moves under the mask device from a first roller set to a second roller set.

### CROSS-REFERENCE TO RELATED APPLICATION(S)

This application claims the benefit of U.S. Provisional Patent App. No. 63/113178, filed Nov. 12, 2020, which is incorporated by reference herein in its entirety.

### TECHNICAL FIELD

The present disclosure relates to method and apparatus for depositing thin sputtered film, and in particular, for depositing nanoscale thin layer on a flexible substrate.

### BACKGROUND

A reel-to-reel sputtering apparatus is widely used as a thin film deposition. One of the reasons for the widespread use is a high productivity with a low running cost. In general, a reel-to-reel plasma sputtering system enables manufacturing various devices by depositing thin film layers onto a substrate as the substrate moves through a high vacuum plasma sputtering chamber. The microstructure and morphology of growing film may be determined by certain factors of energy and direction of sputtered atoms. Sputtered atoms from a sputtering target collide with gas particles present in the vacuum chamber during transport to the substrate, and the collisions can change the atomic energy, direction, and momentum. Thus, the flux distribution of sputtered atoms is nonuniform. As such, it is crucial to develop a new technique or apparatus for achieving highly uniform thin film growth by a reel-to-reel sputtering system.

Generally speaking, the term sputtering is often referred to one of physical vapor deposition methods, in which the deposition process starts with ejection of atoms by bombardment between energetic ions and the surface of a sputtering target. All sputtered atoms leaving the target surface are enabled to collide with the gas atoms present in a vacuum chamber while moving to the substrates. The collisions change the atom direction, energy, and momentum, thereby affecting the microstructure and morphology of growing films. Hence, the important parameters determining the microstructure and morphology of the growing film include energy of bombarding ions and gas pressure.

To explain the energy and angular distribution of sputtered atoms leaving the target, Sigmund-Thompson theory is utilized because nearly all other analytical models of the sputtering process are dependent on the Sigmund-Thompson theory. Based on Sigmund-Thompson theory, it is available to separate the collision cascade into three regimes: the single-knock-on regime, the linear cascade regime, and the spike regime, which are determined by the incident energy of bombarding ions. For example, the single-knock-on regime, the linear cascade regime, and the spike regime are characteristic of the lowest incident energy, several hundreds to KeV energy, and MeV energy, respectively. In the single-knock-on regime, the energy is transferred from ions in the plasma to target surface when the ions are bombarded to the target atoms. A small number of one-to-one collisions are possibly generated. In the linear and the spike regime, the recoiled target atoms are vigorous enough to produce secondary and higher generation recoils.

In this regard, a cascade of recoils is produced, and some atoms at the target surface may be escaped. This regime is named linear because the sputter yield is proportional to the applied power on the target material. In the spike regime, the density of recoiled atoms is sufficiently high to generate collisions between two moving atoms. In a quantitative respect, the regimes can be distinguished by the range of bombarding particle's energy. The single-knock-on regime, the linear cascade regime, and the spike regime are characteristic for bombarding particles with the lowest incident energy, several hundreds to KeV energy, and MeV energy, respectively. Since the bombarding particles in the magnetron sputtering consist of the range of several hundreds' eV energy, the linear cascade regime has been the main concern.

The sputtering yield may be expressed as the number of sputtered atoms per bombarding ions. In case for low energy ion bombardment (hundreds' eV), the sputter yield may be expressed as shown below:

$$Y \vert ( E ) = 0.042 \frac{Q ( {Z}_{2} ) α ( {M}_{2} \text{/} {M}_{1} )}{{U}_{2}} {\frac{{S}_{n} ( E )}{1 + Γ k {ɛ}^{0.3}} [ 1 - \sqrt{\frac{{E}_{th}}{E}} ]}^{n}$$

where E is the energy of bombarding ion, and M1 and M2 are the masses of the ion and the target atom. α is a dimensionless parameter associated with the ion energy and mass ratio between the ion and the target atom. Us is the surface binding energy of the target. Based on the equation, M1=M2 means the bombarding ions transfers its maximum momentum to the target atoms. This momentum transferred from ion bombardment should overtake the surface barrier (Us) to sputter an atom from the target.

FIG. 1(a) shows the situation after atom moves out from the target. In the present disclosure, E, v, and θ stand for the energy, velocity, and direction of the sputtered atom. According to Sigmund-Thompson, both the angular distribution and energy of the sputtered atoms are expressed by an expression as shown in FIG. 1(b). Further, the sputtered atoms have its maximum energy distribution at Nₘₐₓ=U₅/2(1−m), and the angular distribution of the sputtered atoms is based on a cosine function, as shown in FIG. 1(c).

In the magnetron sputtering system, ejection positions of the sputtered atoms are according to a racetrack of a magnetron. The sputtered atoms are ground-state atoms, and these are elastically collided with neutral gas atoms because of two reasons. The first reason for the collision is the very low ionization degree. The number of ionized atoms per total gas atom in the chamber is ˜0.1%. The second reason for the collision is that the density of the sputtered atoms is much less than the neutral gas density. Based on these reasons, the passage of sputtered atoms through the plasma and neutral gas atoms can be considered as a sequence of straight trajectories, which may be stopped by a binary elastic collision with a gas atom. As such, the free path length until the next collision depends on the velocity of the sputtered atoms V.

However, the existing technology has many shortcomings and challenges. By way of example, among many other challenges, it is often difficult to achieve highly uniform ultra-thin film deposition with a controlled deposition rate on a flexible substrate. Many others have tried to overcome this film non-uniformity problems using a hybrid of alternating current (AC) and radio frequency (RF) combination power, a specially shaped linear magnetron sputtering target, or a continuously rotating sputtering target, all of which result in increases in the manufacturing costs as well as decreases in the production throughput because of issues relating to equipment reliability, equipment maintainability load/unload times, and production yield. As such, there is still a need for advanced methods and techniques for overcoming these challenges relating to the reel-to-reel sputtering deposition of ultra-thin films on a flexible substrate.

### SUMMARY

The present technology disclosed herein overcomes the challenges in a cost-effective manner as well as provides advanced features for a reel-to-reel sputtering system. In view of the challenges of the existing technology, the present technology eliminates one or more major hurdles relating to the existing reel-to-reel sputtering deposition of ultra-thin films on a flexible substrate during the plasma deposition process, in various aspects of the present disclosure.

In an aspect of the present disclosure, an apparatus for depositing a thin sputtered film in a deposition chamber is provided. By way of example, the apparatus includes a processing chamber, one or more sputtering devices in the processing chamber, a mask device disposed in the processing chamber, mask supporters coupled to the mask device, a first roller set, a second roller set, and a flexible substrate. The flexible substrate may be configured to move from the first roller set to the second roller set.

In an aspect of the present disclosure, the apparatus may further include a first vacuum chamber and a second vacuum chamber, wherein the first roller set is disposed in the first vacuum chamber. Further, the flexible substrate is configured to move from/to the first roller set to/from the second roller set, while the one or more sputtering devices are activated to sputter atoms on the substrate through the mask device.

in an aspect of the present disclosure, the one or more sputtering devices include either a direct current (DC) power sputtering device or a radio frequency (RIF) power sputtering device.

In an aspect of the present technology, the one or more sputtering devices include a dual-purpose sputtering device configured to provide a DC power sputtering and/or RF power sputtering.

In an aspect of the present technology, the one or more sputtering devices are coupled to the processing chamber via one or more rotary mechanisms.

In an aspect of the present disclosure, the mask device is configured to include two sliding doors and wherein the two sliding doors are in an open position such that sputtered atoms arrive at the flexible substrate through an opening, forming a deposition film having a uniform thickness.

In an aspect of the present disclosure, the opening is formed by the two sliding doors of the mask device and the two sliding doors are separated a distance of 9 cm apart from each other.

In an aspect of the present disclosure, the one or more sputtering devices are disposed to have a distance of 2 cm-6 cm away from the flexible substrate disposed in the processing chamber.

In another aspect of the present disclosure, the apparatus further includes one or more target materials coupled to the one or more sputtering devices.

In another aspect of the present disclosure, wherein the second vacuum chamber is disposed in a glove box coupled to the processing chamber of the reel-to-reel sputtering system.

In another aspect of the present disclosure, the apparatus further includes a real-time monitoring system, an automatic deposition control system, and a user interface.

In another aspect of the present disclosure, the automatic deposition control system in configured to: receive a target type and a desired film thickness, and determine a discharge power, a chamber pressure, and a speed of the flexible substrate.

### BRIEF DESCRIPTION OF THE DRAWINGS

A more detailed understanding may be obtained from the following description in conjunction with the following accompanying drawings.

FIGS. 1 (a), (b), and (c) conceptually illustrate aspects of sputtering in accordance with an aspect of the present disclosure;

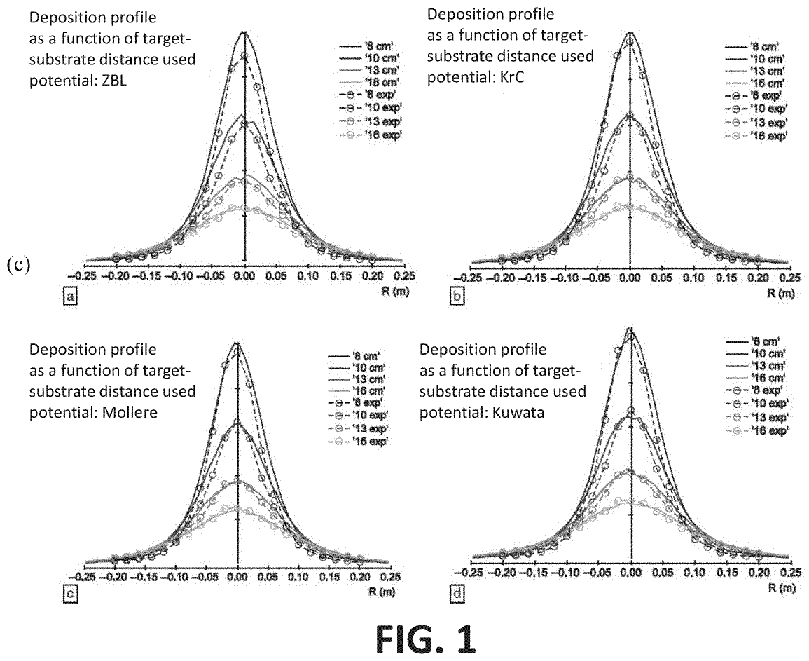

FIG. 2A is a diagram conceptually illustrating an example system in accordance with an aspect of the present disclosure;

FIG. 2B is a diagram conceptually illustrating an example system in accordance with an aspect of the present disclosure;

FIG. 2C is a diagram conceptually illustrating another example system in accordance with an aspect of the present disclosure;

FIG. 3 is a diagram conceptually illustrating an exemplary reel-to-reel sputtering device in an aspect of the present disclosure;

FIGS. 4 (a), (b), (c) are diagrams conceptually illustrating an exemplary embodiment of a mask device in accordance with an aspect of the present disclosure;

FIG. 5 is another diagram conceptually illustrating an exemplary embodiment of the present technology in accordance with an aspect of the present disclosure;

FIG. 6A illustrates an exemplary embodiment of the present technology in accordance with an aspect of the present disclosure;

FIG. 6B illustrates another exemplary embodiment of the present technology in accordance with an aspect of the present disclosure;

FIG. 7A illustrates another exemplary embodiment of the present technology in accordance with an aspect of the present disclosure;

FIG. 7B illustrates another exemplary embodiment of the present technology in accordance with an aspect of the present disclosure;

FIG. 7C illustrates another exemplary embodiment of the present technology in accordance with an aspect of the present disclosure;

FIG. 8 is a graphical representation of data conceptually illustrating an exemplary embodiment of the present technology in accordance with an aspect of the present disclosure;

FIG. 9 is a diagram conceptually illustrating an exemplary embodiment of the present technology in accordance with an aspect of the present disclosure;

FIG. 10 is another graphical representation of data conceptually illustrating an exemplary embodiment of the present technology in accordance with an aspect of the present disclosure;

FIG. 11 is another graphical representation of data conceptually illustrating an exemplary embodiment of the present technology in accordance with an aspect of the present disclosure; and

FIG. 12 conceptually illustrates sputtering condition, thickness profiles, surface morphology, and surface structure, in accordance with an aspect of the present disclosure;

FIG. 13 is galvanostatic charge/discharge (CCD) profiles in accordance with an aspect of the present disclosure; and

FIG. 14 is a diagram conceptually illustrating another exemplary embodiment of the present technology in accordance with an aspect of the present disclosure.

### DETAILED DESCRIPTION

The detailed description of illustrative examples will now be set forth below in connection with the various drawings. The description below is intended to be exemplary and in no way limit the scope of the claimed invention. It provides detailed examples of possible implementation(s), and as such they are not intended to represent the only configuration(s) in which the concepts described herein may be practiced. The detailed description includes specific details for the purpose of providing a thorough understanding of various concepts, and it is noted that these concepts may be practiced without these specific details. In some instances, well known structures and components are shown in block diagram form in order to avoid obscuring such concepts and like reference numerals are used in the drawings to denote like elements and features.

It is also noted that in some instances while the methodologies are described herein as a series of steps or acts, for the purpose of simplicity it is to be understood that the claimed. subject matter is not limited by the order of these steps or acts, as some steps or acts may occur in different orders and/or concurrently with other acts from that shown and described herein. Further, not all illustrated steps or acts may be required to implement various methodologies according to the present technology disclosed herein. Also, it should be appreciated that the apparatus and methods described herein may be utilized separately or in combination with other aspects of the present disclosure, or in combination with conventional technology, without departing from the teachings of the present disclosure.

The present disclosure relates to an apparatus and reel-to-reel antioxidation sputtering method for growing one or more highly uniform thin films on a flexible substrate. The target materials may include metals and transition metal dichalcogenides (TMDs), and substrates are flexible metals.

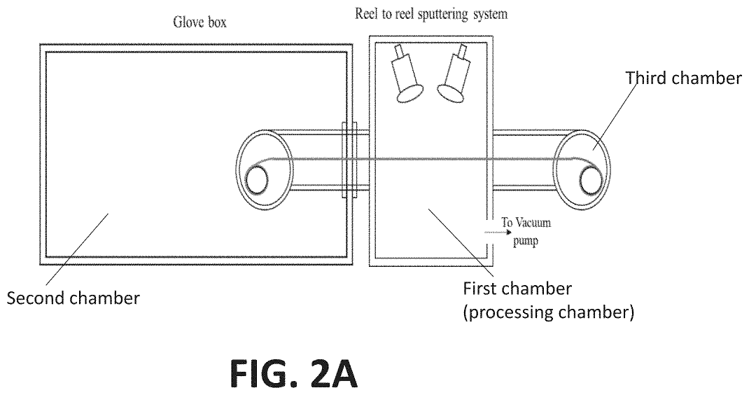

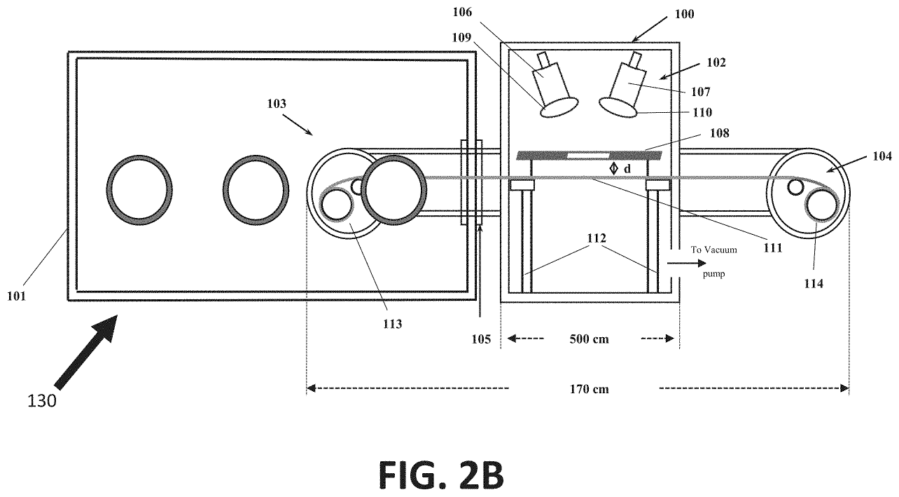

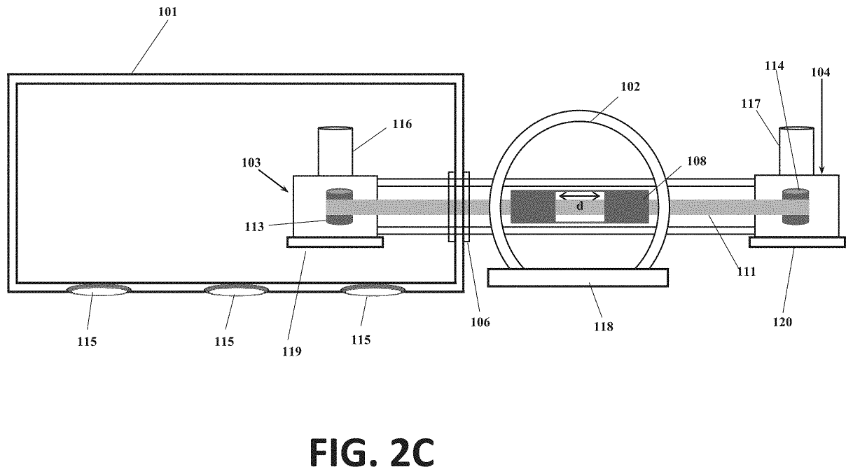

In an aspect of the present disclosure, by way of example, FIG. 2A shows a diagram conceptually illustrating an apparatus in accordance with an aspect of the present technology. The apparatus includes a reel-to-reel sputtering system including a first chamber, an external glove box including a second chamber, and a third chamber. In the example, the reel-to-reel sputtering system is attached or combined with the external glove box to prevent oxidation and miniaturization of growing films in the sputtering system. That is, the edge of the reel-to-reel sputtering system may be attached and hermetically sealed to the edge of the glove box in such a way that the reel-to-reel sputtering system forms a customized reel-to-reel antioxidation plasma vacuum deposition system including one or more magnetron sputtering devices. Further, as shown in FIG. 2A, a first reel-to-reel wheel is disposed in the second chamber placed inside of the external glove box, and a second reel-to-reel wheel is disposed in the third chamber. A flexible substrate may be wound from the first reel-to-reel wheel to the second reel-to-reel wheel through the processing chamber (e.g., a plasma processing chamber) of the reel-to-reel sputtering system. While the plasma is generated, the reel-to-reel process moves the wound flexible substrate forward and backward (or from left to right in the diagram). In the example, operational parameters, such as the discharge power, chamber pressure, and substrate speed may be varied to control a thickness of a growing film in the processing chamber.

By way of example, in an aspect of the present disclosure, FIG. 2A illustrates a high level view of a reel-to-reel antioxidation sputtering system for depositing thin films, for example, deposition of ceramic and metal films. FIG. 2B illustrates a top view of the reel-to-reel antioxidation sputtering system as shown in FIG. 2A.

FIG. 2A is a front or side view of a reel-to-reel sputtering system 100 coupled to a glove box 101 in accordance with an aspect of the present disclosure. The reel-to-reel sputtering system 100 includes a deposition chamber (or processing or first vacuum chamber) 102, a second vacuum chamber 103, and a third vacuum chamber 104. In the example, the glove box 101 provides the second vacuum chamber 103. Further, in the example, the reel-to-reel sputtering system 100 and the glove box 103 are connected via sealing equipment 105 so that a secure passage between the first or processing vacuum chamber 102 and the second vacuum chamber 103 may be established. Furthermore, the first vacuum chamber (or deposition chamber) 102 is configured to include one or more sputtering target holders or sputtering devices.

In the example, the deposition chamber 102 may include a direct current (DC) power sputtering device 106 and/or a radio frequency (RF) power sputtering device 107 disposed in the deposition chamber 102. The deposition chamber 102 of the reel-to-reel sputtering system 100 may further include a mask device 108 and substrate supporters 112. The mask device 108 is configured to be a size adjustable aperture 108 and positioned between sputter targets such as a first sputter target 109 and a second sputter target 110 and a flexible substrate foil 111 in the deposition chamber 102. In the example, the first sputter target 109 is coupled to the DC power sputtering device 106 and a second sputter target 110 is coupled to the RF power sputtering device 107. Also, the substrate supporters 112 are disposed below the substrate foil 111.

In an aspect of the present disclosure, in preparation for operation of the apparatus 130, sputter target materials such as target materials 109, 110 may be installed in each target holder or sputtering devices 106, 107 inside the deposition chamber 102. Further, the substrate foil 111 may be installed between the first roller set 113 and the second roller set 114, prior to the operation of the apparatus 130. For example, a rolled substrate foil may be prepared in advance and placed on the second roller set 114 through a third vacuum chamber door (not shown) and then on the first roller set 113 through a second vacuum chamber door (not shown) and the glove box. Further, before installation of the substrate foil 111, two dummy foils such as thin copper dummy foils may be rolled up both the first winding/unwinding roller set 113 and the second winding/unwinding roller set 114, separately. Also, the edge of the substrate foil 111 may be bound to an edge of the dummy foil which is rolled up the first roller set 113, and the other edge of the substate foil 111 may be bound to the edge of the dummy foil rolled up on the second roller set 114.

In an aspect of the present disclosure, as shown in FIG. 2C, a speed of the two rollers 112, 114 may be controlled by a first motor 116 for the first roller set 113 and a second motor 117 for the second roller set 114. After the installation of the substrate foil 111 and targets, air in the chambers including the deposition chamber 102, the second vacuum chamber 103, and the third vacuum chamber 104, may be removed by a vacuum pump (not shown) connected to the apparatus 130. After removing the air in the apparatus 130, then the chambers may be filled with an inert gas such as argon so that air or oxygen sensitive target materials may be used.

In another aspect of the present disclosure, for the operation of the reel-to-reel sputtering system 100, a process gas for creating plasma may be filled in the processing chamber 102 and a negative bias may be applied to the sputtering devices disposed inside the processing chamber, for a deposition process of a thin film or film growth on a flexible substrate. By way of example, in one implementation, the negative bias may be applied to the first sputtering device 106 for metal film growth and to the second sputtering device for ceramic film growth. When the substrate foil 111 (including a first dummy substrate, a substrate foil, and a last dummy substrate) is moved toward the third vacuum chamber 104 from the second vacuum chamber 103, atoms are sputtered and the sputtered atoms may arrive at the first dummy substrate, the substrate foil 111, and the last dummy substrate, through the mask device 108, as the substrate foil 111 is moved from the first roller set 113 to the second roller set 114.

In the example, the speed of the substate foil 111 may be controlled by the first motor 116 coupled to the first roller set 113 and the second motor 117 coupled to the second roller set 114. In another aspect of the present disclosure, for the deposition of a composite film, negative biases may be applied to both the first sputtering device 106 and the second sputtering device 107 simultaneously. Further, in another aspect of the present disclosure, for the deposition of a multi-stacked film, the negative bias may be applied to the first sputtering device 106 as the substate foil 111 moves in the direction towards the third vacuum chamber 114 for a first film growth, and then a negative bias may be applied to the second sputtering device 107 as the substate foil 111 moves in the direction towards the second vacuum chamber 103 for a second film growth. That is, the substrate foil 111 may move back and forth between the first and second roller sets as different sputtering devices are engaged. Further, after the completion of the deposition process of thin films, the substrate foil 111 may be rolled in the second vacuum chamber 103 and moved to the inside of the glove box 101 from the second vacuum chamber 103 after argon gas is filled in the deposition chamber 102 and the vacuum chambers 103 and 104.

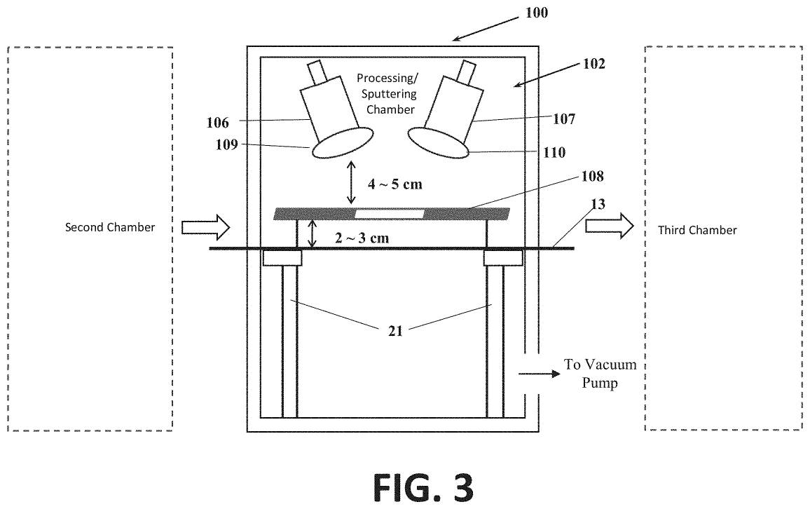

FIG. 3 illustrates a front or side view of a portion of the reel-to-reel sputtering system including a deposition chamber in accordance with an aspect of the present disclosure. In the example, the deposition chamber 102 includes two magnetron devices 106, 107 for sputtering operation in an inert gas, a mask device 108, and two supports or supporting devices 21. In the example, the mask device 108 is disposed between targets 109, 110 and a flexible substrate 13 such that high energy sputtered atoms from the targets 109, 110 may be deposited on the flexible substate 13 with a controlled thickness, as the substrate 13 moves from the second chamber to the third chamber. In the example shown in FIG. 3, the two magnetron devices 106, 107 may include one direct current (DC) power magnetron (e.g., magnetron 106) and radio frequency (RF) power magnetron (e.g., magnetron 107). However, in another implementation, the magnetron devices may be of the same type, either DC or RE power magnetrons, depending on the type of target materials.

In another aspect of the present disclosure, the size dimension of the main sputtering chamber may include a dimension of 45 cm (width) by 60 cm (height). Further, the two target holders may be disposed on a ceiling portion of the deposition chamber 102, and targets 109, 110, for example, ceramic or metal targets may be disposed on the target holders of the respective magnetron devices for operation of depositing a single layer, multi layers, or co-sputtered layers on the flexible substrate 13. Further, in another aspect of the present disclosure, the magnetron devices may be disposed such that a distance of about 4 cm˜5 cm is maintained between the targets and the mask device 108. Also, in the example, the flexible substrate 13 may be disposed a distance of 2 cm-3 cm away from the mask device 108 as the flexible substrate 13 moves from the second chamber to the third chamber, or in a forward direction. Also, as mentioned above, the flexible substrate 13 may move in a backward direction from the third chamber to the second chamber. Further, the apparatus 100 may include two substrate supports 21 under the foil substrate 13 to prevent forming of a convex down shape (e.g., sagging) of the flexible substrate 13. In the example, when the flexible substrate 13 is not flat, it is noted that a thickness of the deposited films may be non-uniform and thus may be out of a desirable range of a film thickness variance.

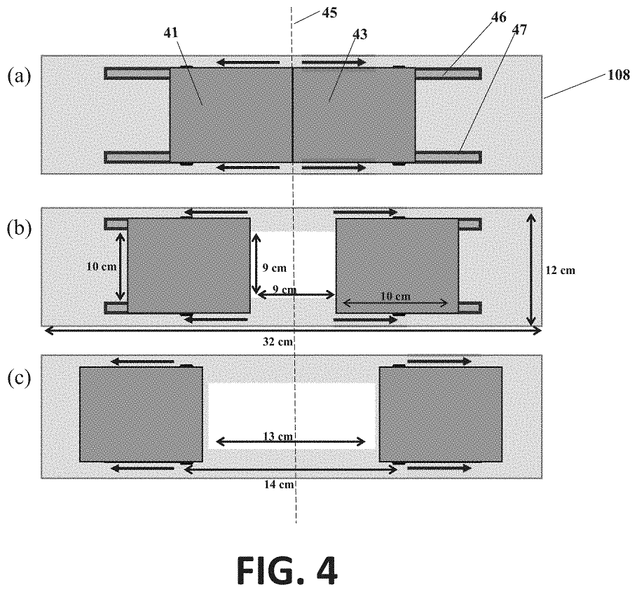

FIG. 4 illustrates an exemplary embodiment of the mask device 108 in accordance with an aspect of the present disclosure. The mask device 108 includes two sliding doors or parts 41, 43 over guides 46, 47 to control the direction and the number of emitted atoms from the sputter targets 109, 110. It is noted that although the sliding doors have a rectangular shape with specific dimensions (e.g., 9 cm by 10 cm) are shown in the example, different sizes and shapes of the sliding doors 41, 43 may be employed. The sliding doors may be in a closed position as shown in FIG. 4(a), and the sliding doors may be in a partially open position having a distance of 9 cm apart between the two sliding doors, as shown in FIG. 4(b). Also, the sliding doors may be in a wide-open position, as shown in FIG. 4(c). In the example, the size and shape of the sliding doors may be targeted for a 4-inch target size and the left and right targets may be tilted 335 degrees and 25 degrees, respectively, off the vertical line in the deposition chamber. The emitted atoms from the sputter targets may not be able to reach the flexible substrate when the sliding doors are in a closed position as shown in FIG. 4(a). On the other hand, when the sliding doors are a wide-open position as shown in FIG. 4(c), the mask device may not be ineffective, depending upon sizes of the sputter targets. For example, it is noted that in a case of the 4-inch target size, the sliding doors in the wide-open position renders the sputtering process do not result desired sputtering results. Based on experimental data collected, in the case of the 4-inch target size, when each sliding door opens 4.5 cm away from a center line 45 toward opposite directions, as shown in FIG. 4(b), the best thickness uniformities may be obtained in the example setting.

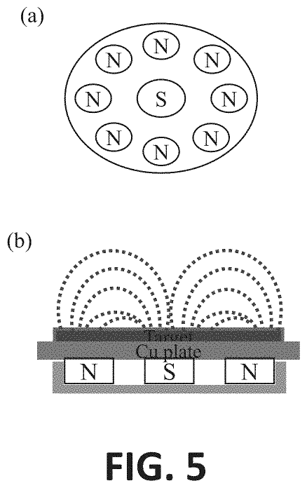

In another aspect of the present disclosure, two parameters are relevant to the design of the present technology. The first parameter is the energy distribution of emitted atoms from a sputtering target. A conventional magnetic plasma sputtering system includes ring-shaped magnets under its target holder as shown in FIG. 5(a), which allows trapping a portion of a magnetic field within the sputtering target. A trapped field creates an additional collision of discharge ions against a surface of the sputtering target to increase a sputtering yield as shown in FIG. 5(b). Also, it is noted that the magnetic field guides the direction of the emitted atoms to the substrate. Thus, the kinetic energy of the emitted atoms may be angularly distributed at the target surface, meaning that the atoms emitted from the center of the sputtering target may have the highest kinetic energy. The energy gradually decreases as it goes to edges of the sputtering target. The second parameter is the distance between the flexible substrate and the sputtering target, which plays an important role in determining deposition profiles of films. The average energy of the emitted atoms may be higher when the distance between the flexible substrate and the sputtering target is short because the emitted atoms elastically collide with gas atoms, e.g., argon, in the vacuum chamber. The sputtered atoms transfer their kinetic energy to the gas atoms when the atoms have elastically collided with each other. As such, the film profiles may be mainly determined by the amount of kinetic energy of the arriving atoms to the flexible substrate. If the arriving atoms have high enough energy to bounce out or move on the surface of the flexible substrate, then sputtered films may consist of straight columns which will reduce the film uniformity. In addition, for obtaining two-dimensional thin film growth, the arriving atoms with high energy may prevent the thickness control, as well.

In an aspect of the present disclosure, to obtain desired sputtering outcomes, these two parameters (e.g., energy distribution of emitted atoms and the distance between the substate and the sputtering target) need to be taken into consideration and controlled. In the example, and in an aspect of the present disclosure, a mask device may be designed and disposed to block the high energy atoms from the sputtering target and to allow the atoms having low energy for depositing on the flexible substrate without bouncing out or moving through the surface. The hole or opening size of the mask device may be in various design and be controlled, depending on the distance between the flexible substrate and the sputtering target.

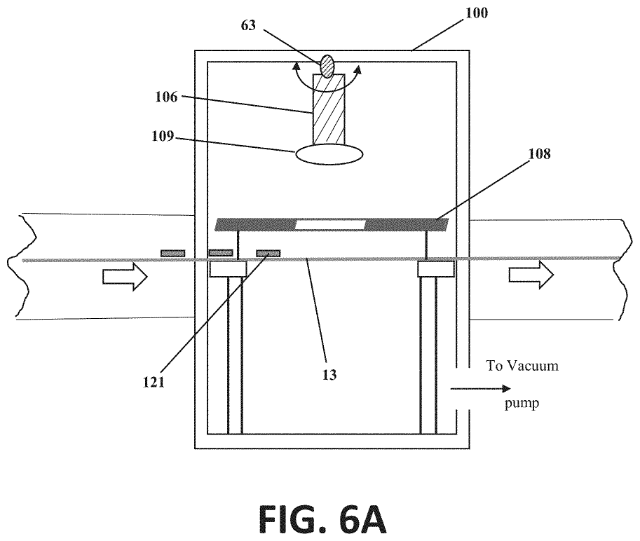

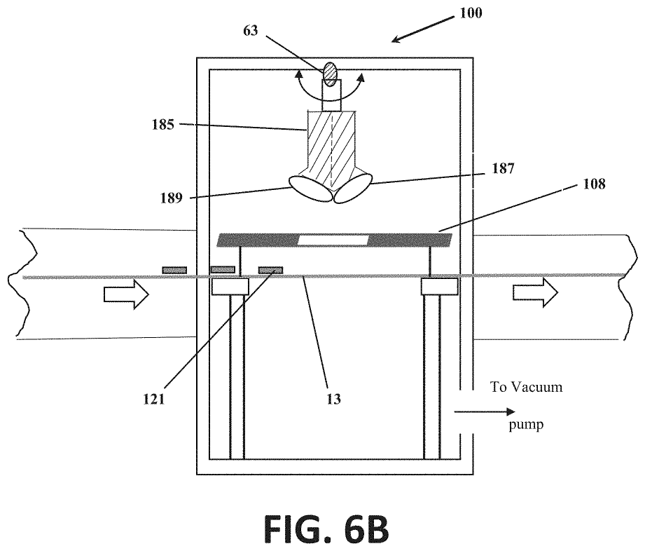

In another aspect of the present disclosure, FIG. 6A illustrates another alternative embodiment of the present disclosure. The embodiment shown in FIG. 6A includes a reel-to-reel sputtering device 100 including a magnetron 106 with a rotary motor mechanism 63 and a sputtering target 109. The magnetron 106 may be is either a DC power magnetron or a RF power magnetron depending on the needs and purposes of the sputtering process. In the example, by means of the rotary motor mechanism 63, the magnetron 106 may be configured to move (back and forth or left or right) or rotate its body with the sputtering target 109 in the deposition chamber, as the sputtering process in operation such that a uniform layer of sputtered atoms may be deposited on samples 121 on a flexible substrate 13, as the flexible substrate 13 moves under the mask device 108. In another aspect of the present disclosure, the rotary motor mechanism 63 may be controlled via a remote controller device (which is not shown).

In another aspect of the present disclosure, FIG. 6B illustrates another embodiment of the present disclosure. The embodiment of FIG. 6B includes a dual-purpose single magnetron 185. The dual-purpose single magnetron 185 may include a combined functionality of DC power and RF power magnetron functions. The magnetron device 185 may be configured to accommodate two different types of sputtering materials such as a first type (e.g., metal) 187 and a second type (e.g., ceramic) 189. In one example mode of operation, the DC power magnetron function may be engaged to sputter the metallic target 187 and the RF power magnetron function may be engaged to sputter the ceramic target 189. Further, the rotary mechanism 63 may be configured to move the magnetron device 185 so that a desired sputtering target is aligned in a direction such that deposition of films with a controlled deposition thickness may be accomplished on the flexible substrate (or on the samples 121) through the mask device 108.

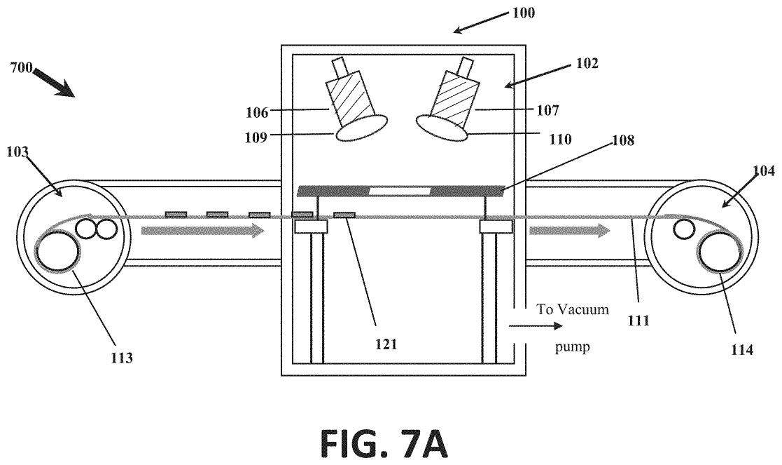

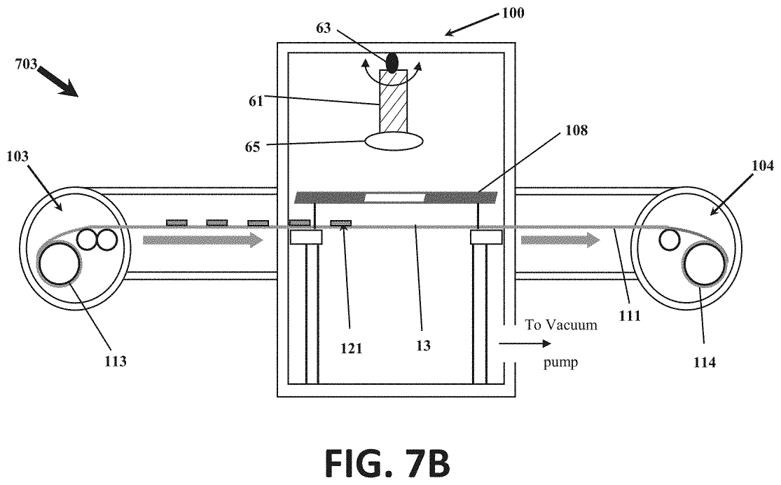

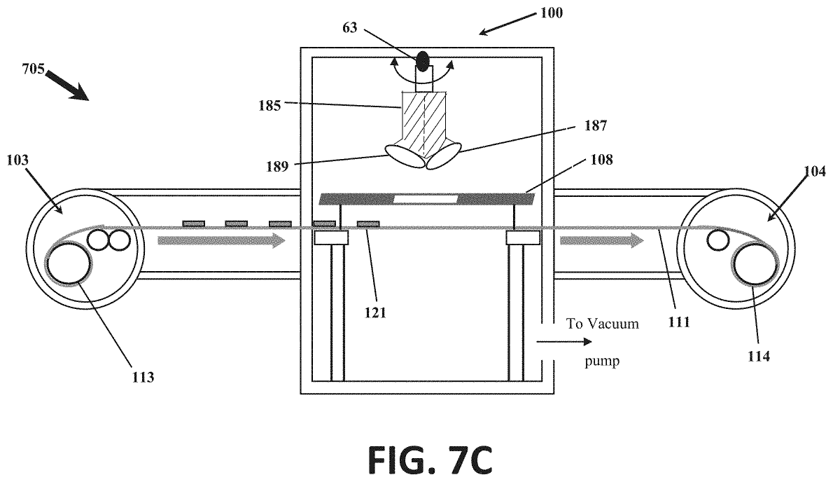

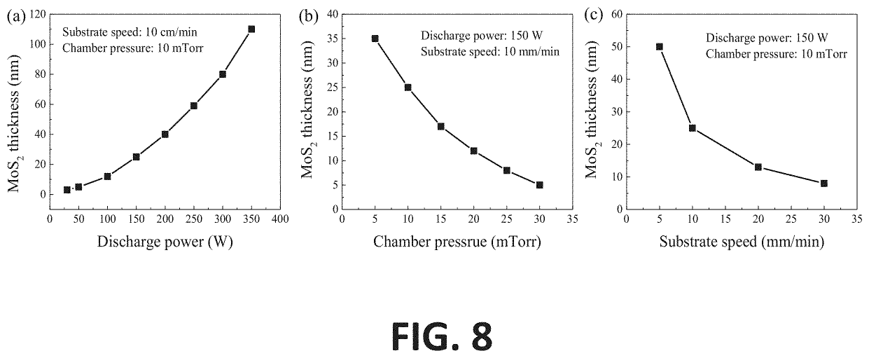

In another aspect of the present disclosure, FIGS. 7A, 7B and 7C provide other exemplary embodiments of a reel-to-reel sputtering system, in accordance with various aspects of the present disclosure. The exemplary embodiments show various possible variants the reel-to-reel sputtering system that can be employed. Further, in an aspect of the present disclosure, the effects of operational parameters such as a discharge power, chamber pressure, and substrate speed on a thickness of deposited films are investigated using the exemplary embodiment of FIG. 7A. Based on numerous controlled experiments, it is observed that the operational parameters are key parameters in controlling and maintaining the thickness of a growing film on the flexible substrate. By way of example, FIG. 8 shows experimental data based on the experiments carried out. That is, FIG. 8 shows preliminary thickness variation data obtained over varying parameters. In FIG. 8, to determine the controlling factors in maintaining a uniform thickness of a deposition film, a molybdenum disulfide (MoS₂) target and a silicon substrate are used. In the example, the MoS₂ target is installed in one target holder having a RF power generator RF power magnetron device) because the MoS₂ target is classified as a ceramic target, which needs RF power to generate a constant plasma environment. During which a single silicon substrate is moved from the second chamber to third chamber, while three parameters, including the discharge power, chamber pressure, and substrate speed were varied and monitored. FIG. 8(a), (b), and (c) show resulting thickness data. In particular, FIG. 8(a) shows that the thickness of MoS₂ films is observed to increase from a few nanometers to hundred nanometers when the discharge power is applied from 30 W to 350 W. On the other hand, the chamber pressure is determined to negatively affect the growth rate of the deposited films. When the chamber pressure increases from 5 mTorr to 30 mTorr, the MoS₂ film thickness is shown to decrease in proportion, as shown in FIG. 8(b). In the meantime, as shown in FIG. 8(c), the deposited film thickness is shown to linearly decrease with the increasing substrate speed.

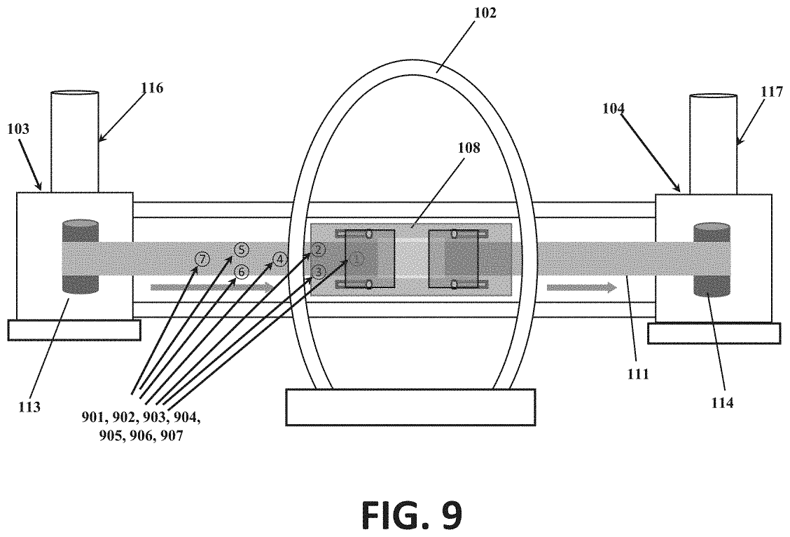

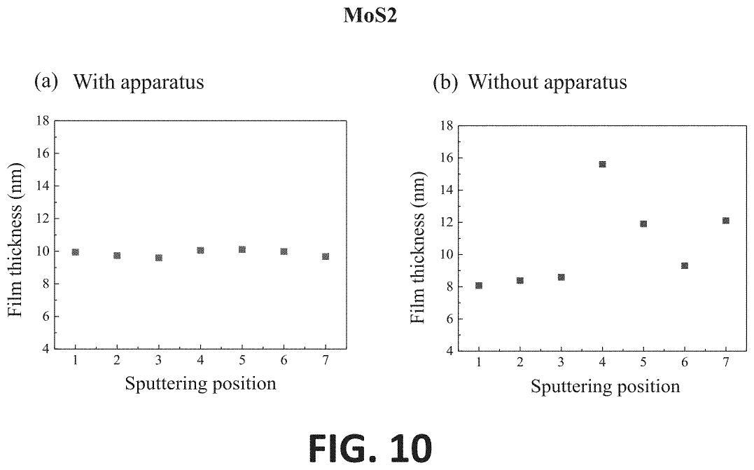

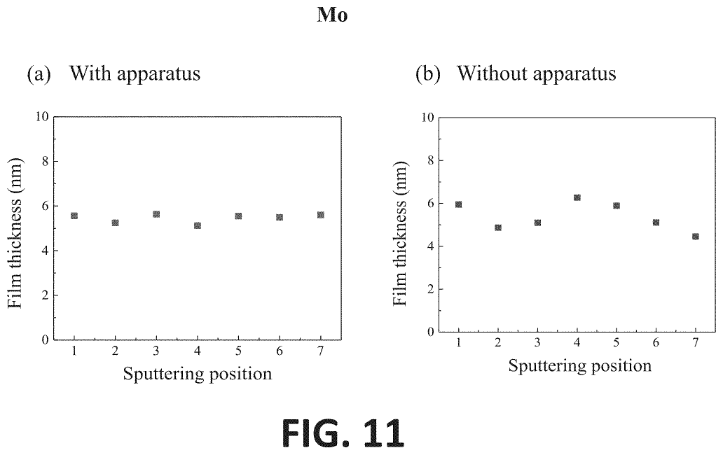

FIGS. 9-11 illustrate another experimental set-up to confirm the thickness uniformity of deposited films over the region of the flexible substrate. In an aspect of the present disclosure, the thickness uniformity of the deposited films was confirmed using the ceramic (MoS₂) and metal (Mo) targets. By way of example, a 50 μm thick copper foil was wound on two reels sets disposed in the second and third chambers, and pieces of silicon substrates are placed on the copper foil as samples, for example, substrate samples 901, 902, 903, 904, 905, 906, and 907, as shown FIG. 9. The silicon substrates then are moved from the second chamber to the third chamber, as the substrates are exposed to vapor phase of the target materials sequentially, and thin MoS₂ or Mo films are deposited on the foil or substrate. To confirm the effectiveness of the mask device 108, thickness results from individual substrate samples 901, 902, 903, 904, 905, 906, and 907 are measured and data are plotted as shown in FIGS. 10 (for MoS₂) and 11 (for Mo). In shown in FIGS. 10 and 11, the sputtering position numbers correspond to the positions of substrate samples, and the distance between each substrate is set to 10 cm. In the example, the applied sputtering conditions are fixed to 100 W, 10 mTorr, and 15 mm/min for MoS₂ film deposition to compare only the thickness uniformity among different sample positions with and without the mask device. As shown in FIG. 10, in case of the thicknesses of deposited MoS₂ films with the mask device 108 (or the apparatus) in place, the average and median values of the film thickness of MoS₂ are calculated to be 9.87 nm and 9.94 nm, respectively, and the average deviation of each observation from the mean is determined to be 0.17 (see FIG. 10(a)). On the other hand, for the case of without the mask device 108 (or apparatus), although the average and the median values are observed to be 10.56 nm and 9.3 nm, respectively, which are similar to the thickness values from using the mask device 108 in place, the average deviation from the thickness of MoS₂ films is shown to be 2.26, which is very large (see FIG. 10(b)).

Further, FIG. 11 shows the results of the thickness uniformity investigation using thin Mo films with and without the mask device 108. For the deposition of thin Mo films, the DC power was used to generate a constant plasma environment, and the operation parameters, such as an applied voltage of 300V, a current of 0.4 A, and a substrate speed of 30 mm/min, are used in the example. As shown in FIG. 11, the average and the median values of the Mo films with and without the apparatus are calculated to be 5.46 nm and 5.55 nm (with the mask device 108 in place) and 5.38 nm and 5.11 nm (without the mask device 108), respectively. Also, the average deviations of observation data from the means are determined to be 0.15 (with the mask device 108 in place) and 0.57 (without the mask device 108). As such, in accordance with an aspect of the present disclosure, the use of the mask device or apparatus 108 in the reel-to-reel sputtering system plays a vital role and effective in controlling and maintaining the thickness uniformity of deposited films on the flexible substrate.

In another aspect of the present disclosure, the present technology may include or combined with one or more of the conventional reel-to-reel techniques. By way of example, in a conventional reel-to-reel sputtering system, the two representative ways are useful for enhance the sputtered film uniformity. First, heat may be used to increase the uniformity of the deposited film thickness. In one example, the heat may be generated to a flexible substrate after the sputtering process is started. A substrate heater that can sustain the substrate at a high temperature may be essential. In such a case, in a vacuum sputtering system, a heating lamp or a heater coil may be used for a heating element. Also, the effect of having an increase in the substrate temperature has been theoretically and experimentally proved that the crystallite size increases with increasing the substrate temperature. Since thermal energy is transferred from the heater to the arriving atoms on the substrate surface, the atoms have enough energy to move until the grain boundaries in the film. The other way to enhance the film uniformity is rotating the target holder. The angular distribution of the atoms leaving the target is highly directional. In addition, in the center part of the target, the largest atoms are emitted with the highest energy than the edge part. All emitted atoms from the target may be capable to collide with gas particles present in the deposition chamber during transport to the substrate. However, in case of the distance between the substrate and the target is close to each other, the emitted atoms may be still directional after colliding with other particles. As such, the rotating target holder during the deposition process of thin films may be helpful to make the deposition of films more uniform by reducing the angular and energy distribution within the target area.

Further, generally, the influence of deposition parameters on morphology and. microstructure of the sputtered film depends on the energy flux sputtered atoms. At low energy of ions, the sputtered atoms will stick to the surface of the substrate and stay in the position because the mobility of sputtered atoms is low to overcome the existing diffusion barrier. Thus, formation of only small crystalline island enables to grow. The grown films have porous structure and reduced density. Hence, overhang structures can be formed. When the energy of the sputtered atoms increases, the mobility also increases, and the film density can be enhanced. The voids in the film begin to be filled with the target atoms and then become a denser film. The mobility of sputtered atoms also affects to grain size and morphology. If the high mobility sputtered atoms arrive to surface of the substrate, the atoms can move to the edge of the crystal or grain due to the high diffusion length; thus, a high mobility result in a lateral growth, whereas a low mobility helpful to a normal growth of the crystal plane. Further, increasing the mobility of sputtered atoms is conducive to the film consisting of straight columns, and then the columns forming the film will enlarge their diameter. In addition, when the energy flux of sputtered atoms surpasses 10 eV, the incident atoms can penetrate into a substrate and form some atomic size voids. Meanwhile, some incident atoms bounce out after a collision with a substrate and then bump against other incident atoms or gas atoms. Therefore, a higher energy flux can form a film having a rough surface and straight column structure.

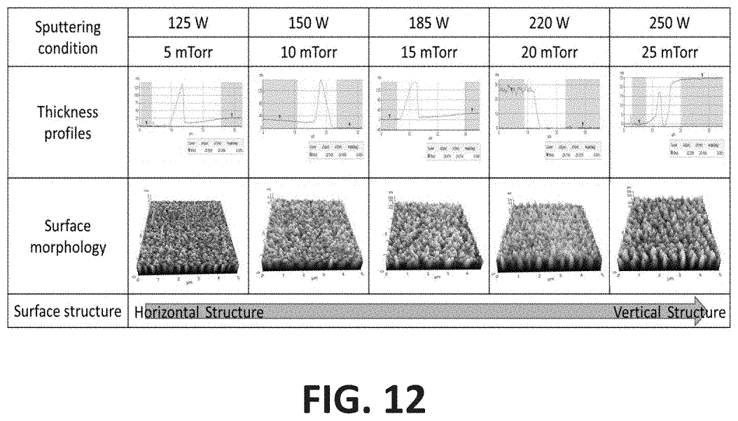

In still another aspect of the present disclosure, an investigation is carried out as to how sputtering conditions affect grain structure variations in the deposited MoS₂ film layers on the substrates. By way of example, while a thickness of deposited MoS₂ layer on Li-metal is set to about 25 nm (±1.5 nm) and the speed of the flexible substrates was set to 10 mm/min, sputtering conditions such as discharge power and chamber pressure are varied from 125 \'V to 250 W and 5 mTorr to 25 mTorr, respectively. Based on the above operational parameters, the surface morphology measurements were investigated using Atomic Force Microscope (AFM) to determine how the grain structure is affected by the varying operational parameters during the sputtering process. The results are shown FIG. 12. As shown in FIG. 12, the varying operational parameters such as sputtering conditions, e.g., discharge power and chamber pressure, affect the grain structure, for example, resulting in a surface structure of a more horizontally aligned or vertically aligned structure. Further, using the above MoS₂ deposited Li-metal anode and CNT-S (carbon nanotube with sulfur) cathode, Li—S coin cells are constructed and galvanostatic charge/discharge (GCD) profiles are obtained.

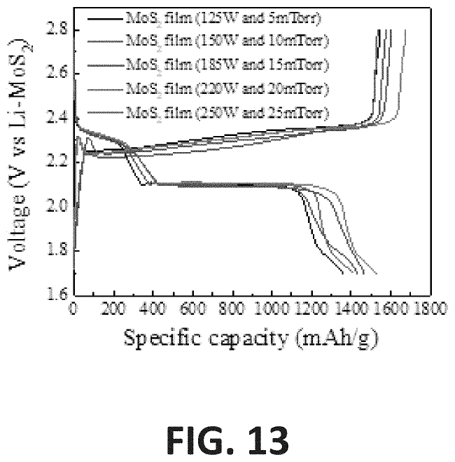

FIG. 13 illustrates exemplary GCD profiles of Li—MoS₂/CNT-S coin cells. GCD profiles of FIG. 13 show that among others, Li—S coin cells with the MoS₂ film at 220 W and 20 mTorr has a specific capacity on the GCD profiles. As shown in FIG. 13, when GCD profiles are measured from Li—MoS₂/CNT-S coin cells with various MoS₂ deposition conditions on Li metal anode, the coin cells with MoS₂ layer with 220 W and 20 mTorr condition (in purple color) show a capacity of around 1600 mAh/g. This confirms that the vertically aligned MoS₂ structures allow more Li ions from bulk Li metal than that of horizontally aligned MoS₂. Based on these findings, it is noted that the concentration of ionic transport through MoS₂ layer may be highly dependent on the grain structure and that the speed of Li ions passing through the vertically aligned structure is more likely to be faster than that of the horizontally aligned structure.

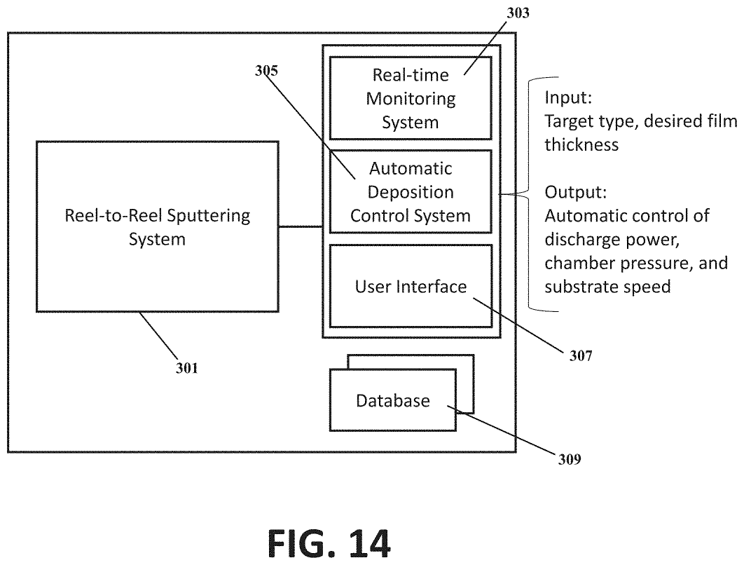

In another aspect of the present disclosure, FIG. 14 illustrates a high-level block diagram conceptually illustrating another embodiment in accordance with an aspect of the present disclosure. The embodiment of FIG. 14 includes a reel-to-reel sputtering system 301 (e.g., the reel-to-reel sputtering device 100), and a subsystem including a real-time monitoring system 303, an automatic deposition control system 305 and a user interface 307, The real-time monitoring system 303 may be configured to monitor operating conditions of the reel-to-reel sputtering system 301, such as its chamber pressure, discharge power, substrate speed, temperature, thickness of deposited layers, etc. while the reel-to-reel sputtering system 301 is continuously operating. Also, when the thickness of deposited layers is monitored, the real-time monitoring system 301 may be connected to one or more image processing and measurement systems including a system for x-ray reflectivity in situ, Ellipsometry, or others to evaluate a sputtered thin film. The user interface 307 may also be an integrated device or a wireless device that is configured to receive user input such as target type, desired film thickness, etc., and to display user determined operational parameters of interest. The automatic deposition control system 305 may be coupled to the real-time monitoring system 303, user interface 307 and the reel-to-reel sputtering system 301 and is configured to control the operating parameters of the reel-to-reel sputtering system 301. In an aspect of the present disclosure, the embodiment may also include and be coupled to one or more databases 309, which store data on target types, deposition thickness data, optimal operating parameters, etc. Also, as one or more embodiments of the present invention are deployed in a large mass scale production environment, data from one or more reel-to-reel sputtering systems may be collected, stored, and used for machine learning to optimally control the operation of each roll-to-roll sputtering system in accordance with the present disclosure. By way of example, various types of targets as well as operating conditions are used and data are collected and analyzed by one or more machine learning software components to extract the optical operating parameters for each type of deposition on a substrate.

As shown above, various methods, techniques, arrangements or their variants may be implemented for artificial trees or plants with capability of producing scent or other features. Other embodiments of the present technology may be possible and are not limited to the disclosed embodiments herein.

Further, as mentioned above, it is noted that as used in the specification and the appended claims, the singular forms “a”, “an”, and “the” include plural referents or one or more items, unless the context clearly indicates otherwise. Also, no element, act, step, or instruction used in the present disclosure should be construed as critical or essential to the present disclosure unless explicitly described as such in the present disclosure. As used herein, except explicitly noted otherwise, the term “comprise” or variations of the term, such as “comprising,” “comprises,” and “comprised” are not used to exclude other additives, components, integers or steps. The term “first,” “second,” and so forth used herein may be used to describe various components, but the components are not limited by the above terms. The above terms are used only to discriminate one component from other components, without departing from the scope of the present disclosure. Also, the term “and/or” as used herein includes a combination of a plurality of associated items or any item of the plurality of associated items. Further, it is noted that when it is described that an element is “coupled” or “connected” to another element, the element may be directly coupled or directly connected to the other element, or the element may be coupled or connected to the element through a third element. Also, the term “include” or “have” as used herein indicates that a feature, an operation, a component, a step, a number, a part or any combination thereof described herein is present. Furthermore, the term “include” or “have” does not exclude a possibility of presence or addition of one or more other features, operations, components, steps, numbers, parts or combinations. It is also noted that the foregoing relates only to exemplary embodiments of the present invention or technology and that numerous modifications or alternations may be made therein without departing from the spirit and the scope of the present disclosure as set forth in this disclosure.

Although the exemplary embodiments of the present disclosure are provided herein, the present disclosure is not limited to these embodiments. There are numerous modifications or alternations that may suggest themselves to those skilled in the art. It is appreciated by one skilled in the art that a wide variety of alternate and/or equivalent implementations may be substituted for the specific examples shown and described without departing from the scope of the present disclosure. As such, the exemplary embodiments should not be construed in any way as imposing limitations upon the scope thereof. On the contrary, it is understood that various other embodiments, modifications, and equivalents thereof which, after reading the description herein, may suggest themselves to those skilled in the art without departing from the spirit of the present invention or disclosure and/or the scope of the appended claims.

What is claimed is:

1. An apparatus for depositing a thin sputtered film, the apparatus comprising:
a reel-to-reel sputtering system including:
a processing chamber,
one or more sputtering devices in the processing chamber,
a mask device disposed in the processing chamber,
mask supporters coupled to the mask device,
a first roller set,
a second roller set, and
a flexible substrate,
wherein the flexible substrate is configured to move from the first roller set to the second roller set.

2. The apparatus of claim 1, further includes:
a second vacuum chamber coupled to one end of the processing chamber; and
a third vacuum chamber coupled to the other end of the processing chamber,
wherein the first roller set is disposed in the second vacuum chamber and the second roller set is disposed in the third vacuum chamber, and
wherein the flexible substate is configured to move from/to the first roller set to/from the second roller set, while the one or more sputtering devices are activated to sputter atoms on the flexible substrate through the mask device.

3. The apparatus of claim 1, wherein the one or more sputtering devices comprise either a direct current (DC) power sputtering device or a radio frequency (RF) power sputtering device.

4. The apparatus of claim 1, wherein the one or more sputtering devices comprise a dual-purpose sputtering device configured to provide a direct current (DC) power sputtering and/or a radio frequency (RF) power sputtering.

5. The apparatus of claim 1, wherein the one or more sputtering devices are coupled to the processing chamber via one or more rotary mechanisms.

6. The apparatus of claim 1, wherein the mask device comprises two sliding doors and wherein the two sliding doors are in an open position such that sputtered atoms arrive at the flexible substrate through an opening, forming a deposition film having a uniform thickness.

7. The apparatus of claim 6, wherein the opening is formed by the two sliding doors of the mask device, the two sliding door being separated a distance of 9 cm apart from each other.

8. The apparatus of claim 6, wherein the one or more sputtering devices are disposed to have a distance of 2 cm-6 cm away from the flexible substrate disposed in the processing chamber.

9. The apparatus of claim 1, further comprising one or more target materials coupled to the one or more sputtering devices.

10. The apparatus of claim 1, wherein the second vacuum chamber is disposed in a glove box coupled to the processing chamber of the reel-to-reel sputtering system.

11. The apparatus of claim 1, further comprising a real-time monitoring system, an automatic deposition control system, and a user interface.

12. The apparatus of claim 11, wherein the automatic deposition control system is configured to:
receive a target type and a desired film thickness, and
determine a discharge power, a chamber pressure, and a speed of the flexible substrate.
